(19) United States
(12) Patent Application Publication
(10) Pub. No.: US 2026/0363104 A1
(43) Pub. Date: Nov. 12, 2026

(54) SEMICONDUCTOR DIES HAVING ELECTRICAL ISOLATION LAYERS AND METHODS OF MAKING THE SAME

(71) Applicant: Taiwan Semiconductor Manufacturing Company Limited, Hsinchu (TW)

(72) Inventors: Sheng-Chi Lin, Hsinchu (TW); Hua-Kai Lin, Taoyuan City (TW); Hao-Yi Tsai, Hsinchu City (TW); Ming Hung Tseng, Toufen Township (TW); Hao-Cheng Hou, Hsinchu City (TW); Chia-Hao Hsu, Hsinchu (TW); Chu-Chun Chueh, Hsinchu City (TW)

(21) Appl. No.: 19/747,049

(22) Filed: Jul. 20, 2026

Related U.S. Application Data
(62) Division of application No. 18/613,172, filed on Mar. 22, 2024.

(51) Int. Cl. H10W 70/63; H10W 90/00; H10W 72/00; H10W 72/20

(52) U.S. Cl. CPC H10W 70/635; H10W 90/00; H10W 72/07252; H10W 72/07255; H10W 72/227; H10W 72/252; H10W 72/257; H10W 90/724

(57) ABSTRACT

An embodiment semiconductor die may include a silicon substrate and a first through-silicon-via (TSV) formed in the silicon substrate, such that the first TSV includes a first protruding portion that protrudes from a surface of the silicon substrate. The embodiment semiconductor die may further include a dielectric isolation layer located between the surface of the silicon substrate and a plane parallel to a first contact surface of the first TSV such that the dielectric isolation layer laterally surrounds the first protruding portion of the first TSV without covering the first contact surface of the first TSV. The semiconductor die may include a redistribution layer including a first redistribution via that forms an electrical connection between the first contact surface of the first TSV and at least one redistribution interconnect. The dielectric isolation layer may prevent an electrically conducting pathway from forming between the first redistribution via and the silicon substrate.

### CROSS-REFERENCE TO RELATED APPLICATIONS

This application is a divisional patent application of U.S. Application No. 18/613,172, entitled “Semiconductor Dies Having Electrical Isolation Layers and Methods of Making the Same” filed Mar. 22, 2024, which is hereby incorporated by reference in its entirety for all purposes.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens, hundreds, or thousands of integrated circuits are typically manufactured on a single semiconductor wafer, and individual dies on the wafer may be singulated by sawing between the integrated circuits along scribe lines. The individual dies are typically packaged separately, in multi-chip modules, or in other types of packaging, for example.

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), 3-dimensional integrated circuits (3DICs), wafer level packages (WLPs), package on package (PoP), System on Chip (SoC) or System on Integrated Circuit (SoIC) devices. Some of these 3-dimensional devices (e.g., 3DIC, SoC, SoIC) are prepared by placing chips over chips on a semiconductor wafer level. These 3-dimensional devices provide improved integration density and other advantages, such as faster speeds and higher bandwidth, because of the decreased length of interconnects between the stacked chips. However, there are many challenges related to 3-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is vertical cross-sectional exploded view of components of a related semiconductor package during a package assembly and surface mounting process.

FIG. 2 is a vertical cross-sectional view illustrating a related assembled semiconductor package mounted onto a support substrate.

FIG. 3A is a vertical cross-sectional view of a further semiconductor package, according to various embodiments.

FIG. 3B is an enlarged vertical cross-sectional view of a portion of the semiconductor package of FIG. 3A, according to various embodiments.

FIG. 4A is a vertical cross-sectional view of a portion of an interposer including a semiconductor die having a dielectric isolation layer, according to various embodiments.

FIG. 4B is a vertical cross-sectional view of a portion of a comparison interposer including a semiconductor die that omits a dielectric isolation layer.

FIG. 5A is a vertical cross-sectional view of an intermediate structure that may be used in the formation of an interposer, according to various embodiments.

FIG. 5B is a vertical cross-sectional view of a further intermediate structure that may be used in the formation of an interposer, according to various embodiments.

FIG. 5C is a vertical cross-sectional view of a further intermediate structure that may be used in the formation of an interposer, according to various embodiments.

FIG. 5D is a vertical cross-sectional view of a further intermediate structure that may be used in the formation of an interposer, according to various embodiments.

FIG. 5E is a vertical cross-sectional view of a further intermediate structure that may be used in the formation of an interposer, according to various embodiments.

FIG. 5F is a vertical cross-sectional view of a further intermediate structure that may be used in the formation of an interposer, according to various embodiments.

FIG. 5G is a vertical cross-sectional view of a further intermediate structure that may be used in the formation of an interposer, according to various embodiments.

FIG. 5H is a vertical cross-sectional view of a further intermediate structure that may be used in the formation of an interposer, according to various embodiments.

FIG. 5I is a vertical cross-sectional view of a further intermediate structure that may be used in the formation of an interposer, according to various embodiments.

FIG. 5J is a vertical cross-sectional view of a further intermediate structure that may be used in the formation of an interposer, according to various embodiments.

FIG. 6A is a vertical cross-sectional view of a further intermediate structure that may be used in the formation of an interposer, according to various embodiments.

FIG. 6B is a vertical cross-sectional view of a further intermediate structure that may be used in the formation of an interposer, according to various embodiments.

FIG. 6C is a vertical cross-sectional view of a further intermediate structure that may be used in the formation of an interposer, according to various embodiments.

FIG. 7A is a vertical cross-sectional view of a further intermediate structure that may be used in the formation of an interposer, according to various embodiments.

FIG. 7B is a vertical cross-sectional view of a further intermediate structure that may be used in the formation of an interposer, according to various embodiments.

FIG. 7C is a vertical cross-sectional view of a further intermediate structure that may be used in the formation of an interposer, according to various embodiments.

FIG. 8A is a vertical cross-sectional view of a portion of an interposer including a semiconductor die having a dielectric isolation layer in a first configuration, according to various embodiments.

FIG. 8B is top view of the portion of the interposer of FIG. 8A, according to various embodiments.

FIG. 9A is a vertical cross-sectional view of a portion of an interposer including a semiconductor die having a dielectric isolation layer in a further configuration, according to various embodiments.

FIG. 9B is top view of the portion of the interposer of FIG. 9A, according to various embodiments.

FIG. 9C is top view of a portion of an interposer in an alternative configuration to that of FIG. 9B, according to various embodiments.

FIG. 10 is a flowchart illustration operations of a method of forming an interposer, according to various embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, this disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Typically, in a semiconductor package, a number of semiconductor integrated circuit (IC) dies (i.e., “chips”) may be mounted onto a common substrate, which may also be referred to as a “package substrate.” In some embodiments, electrical connections to the semiconductor package may be made by mounting the package substrate onto a support substrate containing electrical interconnects, such as a printed circuit board (PCB). A semiconductor package may further include an interposer to which one or more semiconductor dies are attached and electrically coupled. The interposer, in turn, may be attached and electrically coupled to a package substrate, which may be further attached to a PCB. As such, separate structures (e.g., semiconductor dies, interposer, package substrate, and PCB) may be fabricated and then assembled.

Various disclosed embodiments may be advantageous by providing an interposer including a semiconductor die having a dielectric isolation layer formed between a surface of a semiconductor substrate and a plane parallel to a contact surface of an electrical contact of the semiconductor die. In forming redistribution layers over the semiconductor die, some redistribution vias that are intended to be electrically connected to electrical contacts of the semiconductor die may be misaligned due to process variations. Such misalignment may lead to some redistribution vias making partial contact with the respective electrical contacts and making partial contact with the dielectric isolation layer. The presence of the dielectric isolation layer may prevent unwanted electrical leakage between redistribution interconnects/vias and the semiconductor substrate that may otherwise occur in comparative embodiments that do not include the dielectric isolation layer.

An embodiment semiconductor die may include a silicon substrate and a first through-silicon-via (TSV) formed in the silicon substrate, such that the first TSV includes a first protruding portion that protrudes from a surface of the silicon substrate. The embodiment semiconductor die may further include a dielectric isolation layer located between the surface of the silicon substrate and a plane parallel to a first contact surface of the first TSV such that the dielectric isolation layer laterally surrounds the first protruding portion of the first TSV without covering the first contact surface of the first TSV. The semiconductor die may include a redistribution layer including a first redistribution via that forms an electrical connection between the first contact surface of the first TSV and at least one redistribution interconnect. The dielectric isolation layer may prevent an electrically conducting pathway from forming between the first redistribution via and the silicon substrate.

An embodiment interposer may include a semiconductor die and a molding material laterally surrounding the semiconductor die. The semiconductor die may include a semiconductor substrate, a first electrical contact including a first protruding portion that protrudes from a surface of the semiconductor substrate, and a dielectric isolation layer located between the surface of the semiconductor substrate and a plane parallel to a first contact surface of the first electrical contact. The dielectric isolation layer may laterally surround the first protruding portion of the first electrical contact without covering the first contact surface of the first electrical contact. The embodiment interposer may further include a polymer layer formed over the semiconductor die and the molding material such that the polymer layer is at least partially covering the dielectric isolation layer, at least one redistribution interconnect formed in the polymer layer, and a first redistribution via that electrically connects the first contact surface of the first electrical contact and the at least one redistribution interconnect. The dielectric isolation layer may prevent an electrically conducting pathway from forming between the first redistribution via and the silicon substrate.

An embodiment method of forming an interposer may include forming a molding material around a semiconductor die such that the molding material laterally surrounds the semiconductor die. The molding material may be formed such that a side of the semiconductor die, including a first electrical contact formed in a semiconductor substrate, is exposed. The method may further include performing a recess etch process on the semiconductor substrate to remove a portion of the semiconductor substrate such that a first protruding portion of the first electrical contact is protruding from a surface of the semiconductor substrate and depositing a dielectric material over the surface of the semiconductor substrate and the first electrical contact. The method may further include performing a planarization process to remove a portion of the dielectric material to expose a first contact surface of the first electrical contact and to thereby form a dielectric isolation layer that is located between the surface of the semiconductor substrate and a plane parallel to the first contact surface of the first electrical contact. As such, the dielectric isolation layer may laterally surround the first protruding portion of the first electrical contact without covering the first contact surface of the first electrical contact.

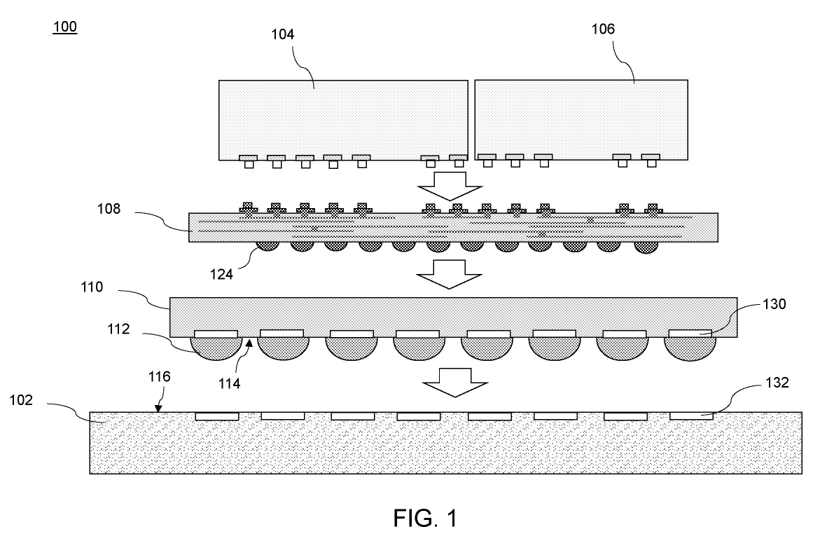

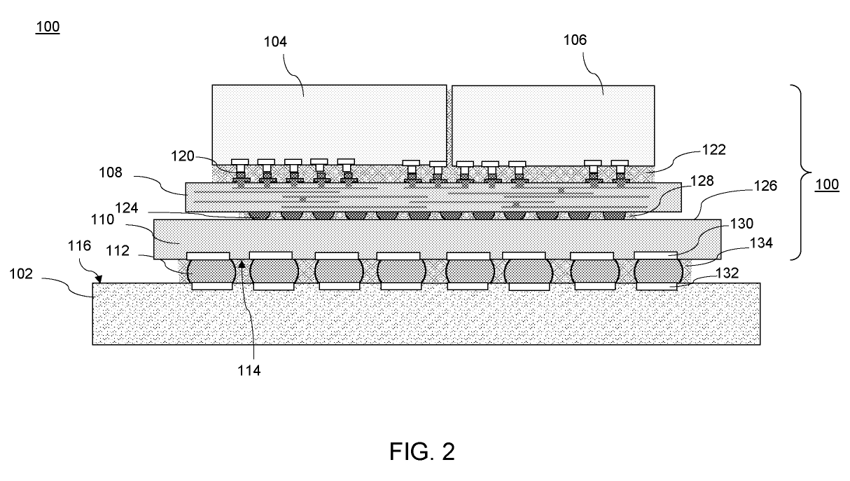

FIG. 1 is vertical cross-section exploded view of components of a related semiconductor package 100 during a package assembly and surface mounting process. FIG. 2 is a vertical cross-section view illustrating the related assembled semiconductor package 100 mounted onto the surface of a support substrate 102, such as a printed circuit board (PCB). The semiconductor package 100 in this example is a chip-on-wafer-on-substrate (CoWoS) semiconductor package, although it will be understood that a similar assembly and mounting process may be utilized for other types of semiconductor packages, such as integrated fan-out (InFO) semiconductor packages, flip-chip semiconductor packages, etc.

Referring to FIGS. 1 and 2, the related semiconductor package 100 may include integrated circuit (IC) semiconductor devices, such as first semiconductor devices 104 and second semiconductor devices 106. During the package assembly process, the first semiconductor device 104 and the second semiconductor device 106 may be mounted on an interposer 108, and the interposer 108 containing the first semiconductor device 104 and the second semiconductor device 106 may be mounted onto a package substrate 110 to form a semiconductor package 100. The semiconductor package 100 may then be mounted to a support substrate 102, such as a printed circuit board (PCB), by mounting the package substrate 110 to the support substrate 102 using an array of first solder balls 112 on the lower surface 114 of the package substrate 110.

A parameter that may ensure proper interconnection between the package substrate 110 and the support substrate 102 is the degree of co-planarity between the surfaces of the first solder balls 112 that may be brought into contact with the mounting surface (i.e., the upper surface 116 of the support substrate 102 in FIG. 1). A low degree of co-planarity between the first solder balls 112 may result in instances of solder cold joints (i.e., insufficient melting of the solder material, resulting in a poor bond that is susceptible to cracking and separation) and/or solder bridging issues (i.e., solder material from one solder ball 112 contacting material from a neighboring solder ball 112, resulting in an unintended connection (i.e., electrical short)) during the reflow process.

Deformation of the package substrate 110, such as stress-induced warping of the package substrate 110, may be a contributor to low co-planarity of the first solder balls 112 during surface mounting of the package substrate 110 onto a support substrate 102. Deformation of the package substrate 110 is not an uncommon occurrence, particularly in the case of semiconductor packages 100 used in high-performance computing applications. These high-performance semiconductor packages 100 tend to be relatively large and may include a number of semiconductor devices (e.g., 104, 106) mounted to the package substrate 110, which may increase a likelihood that the package substrate 110 may be subject to warping or other deformations. Such deformations may present challenges to effective solder mounting of these types of semiconductor package substrates 110 onto a support substrate 102.

In various embodiments, the first semiconductor devices 104 may be three-dimensional devices, such as three-dimensional integrated circuits (3DICs), System on Chip (SoC) or System on Integrated Circuit (SoIC) devices. A three-dimensional semiconductor device 104 may be formed by placing chips over chips on a semiconductor wafer level. These three-dimensional devices may provide improved integration density and other advantages, such as faster speeds and higher bandwidths, due to a decreased length of interconnects between the stacked chips. In some embodiments, a first three-dimensional semiconductor device 104 may also be referred to as a “first die stack.”

The second semiconductor device(s) 106 may be different from the first semiconductor device(s) 104 in terms of their structure, design and/or functionality. The one or more second semiconductor devices 106 may be three-dimensional semiconductor devices, which may also be referred to as “second die stacks.” In some embodiments, the one or more second semiconductor devices 106 may include a memory device, such as a high bandwidth memory (HBM) device. In the example shown in FIGS. 1 and 2, the semiconductor package 100 may include a SoC die stack 104 and an HBM die stack 106, although it will be understood that the semiconductor package 100 may include greater or fewer numbers of semiconductor devices.

Referring again to FIG. 2, the first semiconductor devices 104 and second semiconductor devices 106 may be mounted on an interposer 108. In some instances, the interposer 108 may be an organic interposer including a polymer dielectric material (e.g., a polyimide material) having a plurality of metal interconnect structures extending therethrough. In other instances, the interposer 108 may be a semiconductor interposer, such as a silicon interposer, having a plurality of interconnect structures (e.g., through-silicon vias) extending therethrough. Other suitable configurations for the interposer 108 are within the contemplated scope of the disclosure. The interposer 108 may include a plurality of conductive bonding pads on upper and lower surfaces of the interposer and a plurality of conductive interconnects extending through the interposer 108 between the upper and lower bonding pads of the interposer 108. The conductive interconnects may distribute and route electrical signals between the first semiconductor devices 104, the second semiconductor devices 106, and the underlying package substrate 110.

A plurality of first metal bumps 120, such as microbumps, may electrically connect conductive bonding pads on the bottom surfaces of the first semiconductor devices 104 and second semiconductor devices 106 to the conductive bonding pads on the upper surface of the interposer 108. In one non-limiting embodiment, first metal bumps 120 in the form of microbumps may include a plurality of first metal stacks, such as a plurality of Cu-Ni-Cu stacks, located on the bottom surfaces of the first semiconductor devices 104 and second semiconductor devices 106, and a plurality of second metal stacks (e.g., Cu-Ni-Cu stacks) located on the upper surface of the interposer 108. A solder material, such as tin (Sn), may be located between respective first and second metal stacks to electrically connect the first semiconductor devices 104 and the second semiconductor devices 106 to the interposer 108. Other suitable materials for the first metal bumps 120 and solder material are within the contemplated scope of disclosure.

After the first semiconductor devices 104 and second semiconductor devices 106 are mounted to the interposer 108, a first underfill material portion 122 may optionally be provided in the spaces surrounding the first metal bumps 120 and between the bottom surfaces of the first semiconductor devices 104, the second semiconductor devices 106, and the upper surface of the interposer 108 as shown in FIG. 2. The first underfill material portion 122 may also be provided in the spaces laterally separating adjacent first semiconductor devices 104 and second semiconductor devices 106 of the semiconductor package 100. In various embodiments, the first underfill material portion 122 may include of an epoxy-based material, which may include a composite of resin and filler materials.

Referring again to FIG. 2, the interposer 108 may be mounted on the package substrate 110 that may provide mechanical support for the interposer 108 and the first semiconductor devices 104 and second semiconductor devices 106 that are mounted on the interposer 108. The package substrate 110 may include a suitable material, such as an organic material (e.g., a polymer and/or thermoplastic material), a semiconductor material (e.g., a semiconductor wafer, such as a silicon wafer), a ceramic material, a glass material, combinations thereof, etc. Other suitable substrate materials are within the contemplated scope of present disclosure. In various embodiments, the package substrate 110 may include a plurality of conductive bonding pads (not shown) in an upper surface 126 of the package substrate 110. A plurality of second metal bumps 124, such as C4 solder bumps, may electrically connect conductive bonding pads (not shown) on the bottom surface of the interposer 108 to the conductive bonding pads on the upper surface 126 of the package substrate 110. In various embodiments, the second metal bumps 124 may include a suitable solder material, such as tin (Sn), although other suitable solder materials are within the contemplated scope of disclosure.

A second underfill material portion 128 may be provided in the spaces surrounding the second metal bumps 124 and between the bottom surface of the interposer 108 and the upper surface 126 of the package substrate 110 as illustrated, for example, in FIG. 2. In various embodiments, the second underfill material portion 128 may include an epoxy-based material, which may include a composite of resin and filler materials. In some embodiments, a lid or cover (not shown in FIGS. 1 and 2) may be mounted to the package substrate 110 and may provide an enclosure around the upper and side surfaces of the first semiconductor devices 104 and second semiconductor devices 106.

As described above, the package substrate 110 may be mounted to the support substrate 102, such as a printed circuit board (PCB). Other suitable support substrates 102 are within the contemplated scope of disclosure. The package substrate 110 may include a plurality of conductive bonding pads 130 in a lower surface 114 of the package substrate 110. A plurality of conductive interconnects (not shown) may extend through the package substrate 110 between conductive bonding pads on the upper surface 126 and lower surface 114 of the package substrate 110. The plurality of first solder balls 112 (or bump structures) may electrically connect the conductive bonding pads 130 on the lower surface 114 of the package substrate 110 to a plurality of conductive bonding pads 132 on the upper surface 116 of the support substrate 102.

The bonding pads 130 of the package substrate 110 and bonding pads 132 of the support substrate 102 may be formed of a suitable conductive material, such as copper. Other suitable conductive materials are within the contemplated scope of disclosure. The plurality of first solder balls 112 on the lower surface 114 of the package substrate 110 may form an array of first solder balls 112, such as a ball grid array (BGA) that may include an array pattern that corresponds to an array pattern of the conductive bonding pads 132 on the upper surface 116 of the support substrate 102. In one non-limiting example, the array of first solder balls 112 may include a grid pattern and may have a pitch (i.e., distance between the center of each solder ball 112 and the center of each adjacent solder ball 112). In an example embodiment, the pitch may be between about 0.8 and 1.0 mm, although larger and smaller pitches may be used.

The first solder balls 112 may include any suitable solder material, such as tin, lead, silver, indium, zinc, nickel, bismuth, antimony, cobalt, copper, germanium, alloys thereof, combinations thereof, or the like. Other suitable materials for the first solder balls 112 are within the contemplated scope of disclosure. In some embodiments, the lower surface 114 of the package substrate 110 may include a coating of solder resist (SR) material (not shown), which may also be referred to as a “solder mask”. A SR material coating may provide a protective coating for the package substrate 110 and any underlying circuit patterns formed on or within the package substrate 110. An SR material coating may also inhibit solder material from adhering to the lower surface 114 of the package substrate 110 during a reflow process. In embodiments in which the lower surface 114 of the package substrate 110 includes an SR coating, the SR material coating may include a plurality of openings through which the bonding pads 130 may be exposed.

In various embodiments, each of the conductive bonding pads 130 in different regions of the package substrate 110 may have the same size and shape. In the embodiment shown in FIGS. 1 and 2, the surfaces of the bonding pads 130 may be substantially co-planar with the lower surface 114 of the package substrate 110, which in some embodiments may include a solder resist (SR) coating. Alternatively, the surfaces of the bonding pads 130 may be recessed relative to the lower surface 114 of the package substrate 110. In some embodiments, the surfaces of the bonding pads 130 may be raised relative to the lower surface 114 of the package substrate 110.

Referring again to FIGS. 1 and 2, first solder balls 112 may be provided over the respective conductive bonding pads 130. In one non-limiting example, the conductive bonding pads 130 may have a width dimension that is between about 500 µm and about 550 µm (e.g., ~ 530 µm), and the first solder balls 112 may have an outer diameter that may be between about 600 µm and about 650 µm (e.g., ~ 630 µm), although greater and smaller sizes of the first solder balls 112 and/or the bonding pads 130 are within the contemplated scope of disclosure.

A first solder reflow process may include subjecting the package substrate 110 to an elevated temperature (e.g., at least about 250°C) in order to melt the first solder balls 112 and to cause the first solder balls 112 to adhere to the conductive bonding pads 130. Following the first reflow process, the package substrate 110 may be cooled causing the first solder balls 112 to re-solidify. Following the first solder reflow process, the first solder balls 112 may adhere to the conductive bonding pads 130. Each solder ball 112 may extend from the lower surface 114 of the package substrate 110 by a vertical height that may be less than the outer diameter of the solder ball 112 prior to the first reflow process. For example, where the outer diameter of the solder ball 112 is between about 600 µm and about 650 µm (e.g., ~ 630 µm), the vertical height of the solder ball 112 following the first reflow process may be between about 500 µm and about 550 µm (e.g., ~ 520 µm).

In various embodiments, the process of mounting the package substrate 110 onto the support substrate 102 as shown in FIG. 2, may include aligning the package substrate 110 over the support substrate 102, such that the first solder balls 112 contacting the conductive bonding pads 130 of the package substrate 110 may be located over corresponding bonding pads (e.g., bonding pads 132) on the support substrate 102. A second solder reflow process may then be performed. The second solder reflow process may include subjecting the package substrate 110 to an elevated temperature (e.g., at least about 250° C) to thereby melt the first solder balls 112 and cause the first solder balls 112 to adhere to the corresponding bonding pads 132 on the support substrate 102. Surface tension may cause the semi-liquid solder to maintain the package substrate 110 in alignment with the support substrate 102 while the solder material cools and solidifies. Upon solidification of the first solder balls 112, the package substrate 110 may sit above the upper surface 116 of the support substrate 102 by a stand-off height that may be between about 0.4 mm to about 0.5 mm, although greater or lesser stand-of heights are within the contemplated scope of disclosure.

Following the mounting of the package substrate 110 to the support substrate 102, a third underfill material portion 134 may be provided in the spaces surrounding the first solder balls 112 and between the lower surface 114 of the package substrate 110 and the upper surface 116 of the support substrate 102, as is shown in FIG. 2. In various embodiments, the third underfill material portion 134 may include an epoxy-based material, which may include a composite of resin and filler materials.

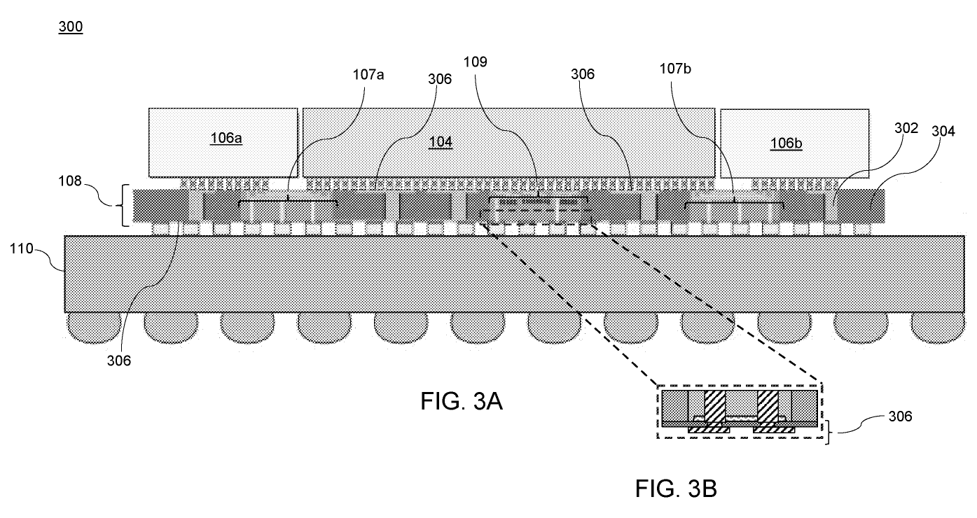

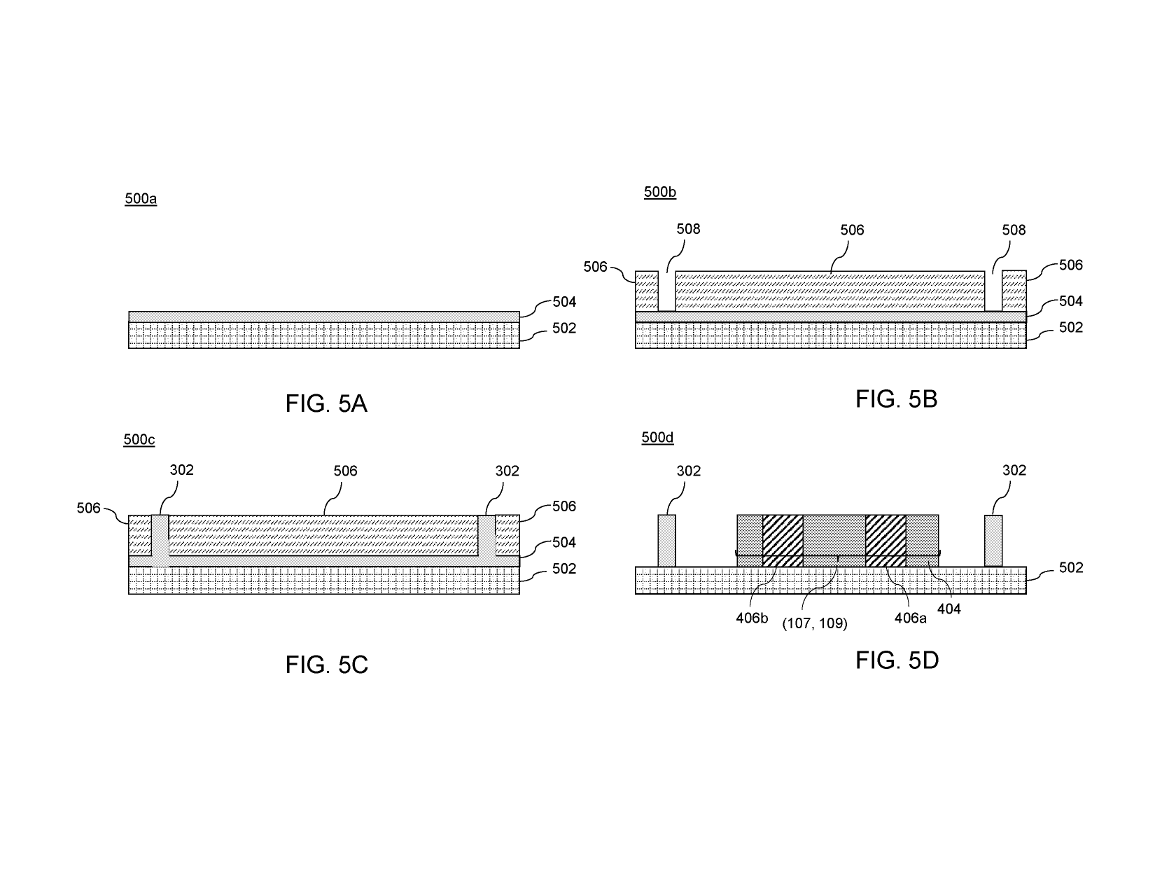

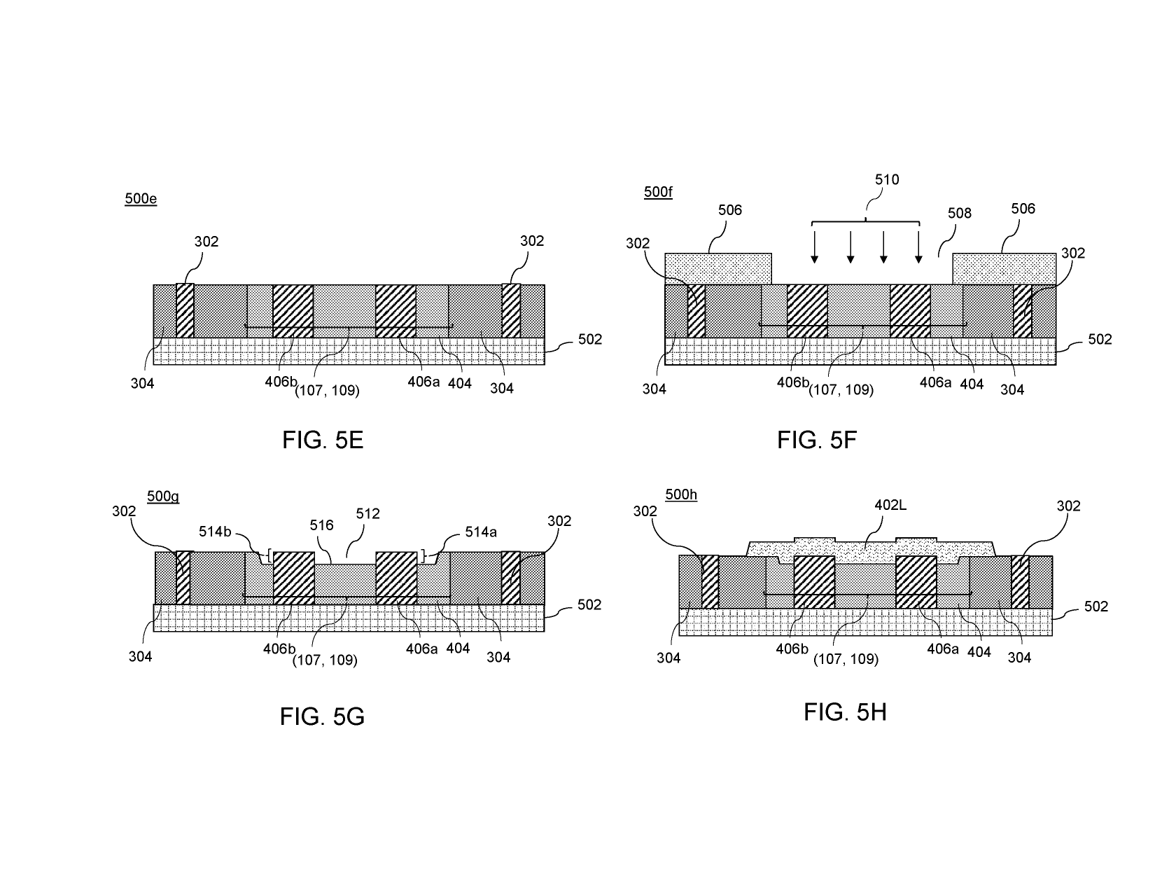

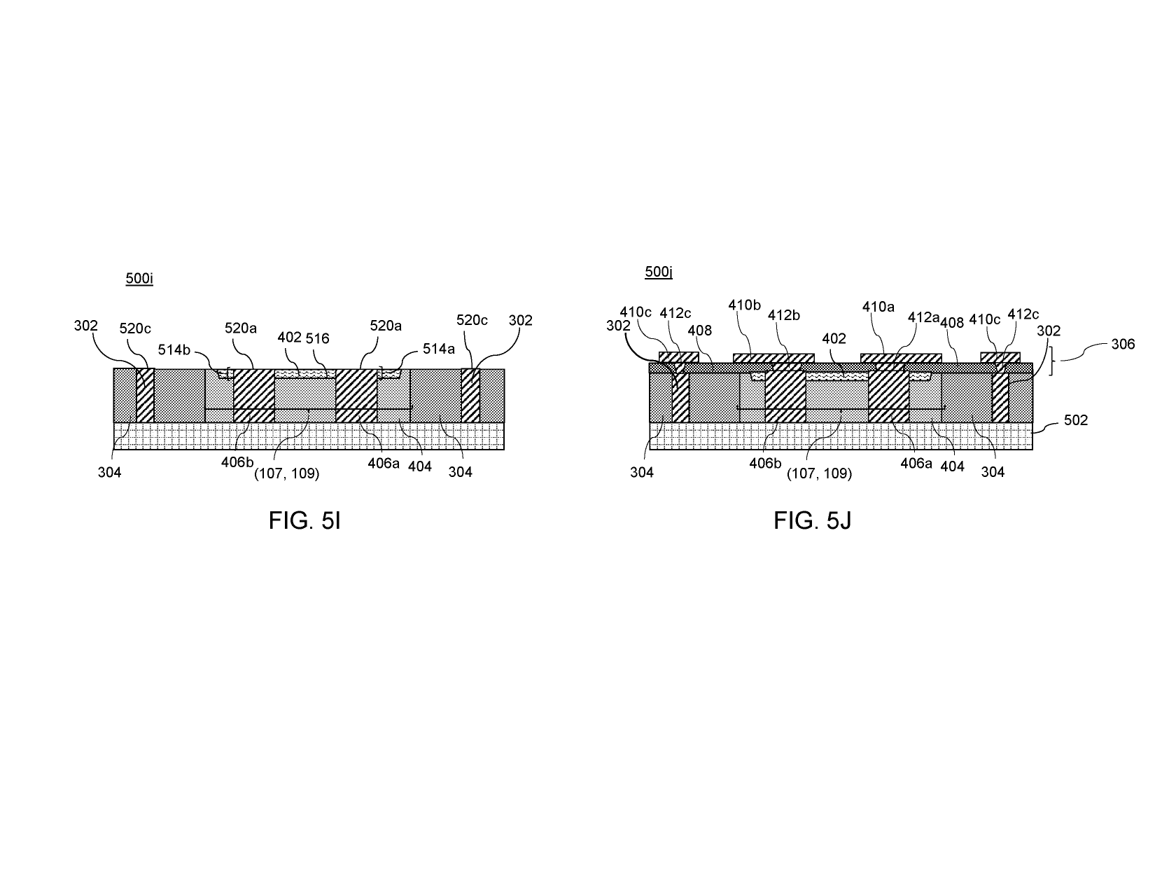

FIG. 3A is a vertical cross-sectional view of a further semiconductor package 300, and FIG. 3B is an enlarged vertical cross-sectional view of a portion of the semiconductor package of FIG. 3A, according to various embodiments. The semiconductor package 300 may include a plurality of semiconductor devices (104, 106a, 106b) attached to an interposer 108. In turn, the interposer 108 may be attached to a package substrate 110. The semiconductor package 300 may be configured as a CoWoS-L package. In this regard, the interposer 108 may be molding-based interposer that may include one or more through-interposer-vias (TIVa) 302. The TIVs 302 may be formed within a molding material 304, as described in greater detail with reference to FIGS. 5A to 5J, below. The molding material 304 may also surround one or more active or passive semiconductor dies (107a, 107b, 109). For example, the interposer 108 may include a first local-silicon-interconnect (LSI) 107a and a second LSI 107b. The interposer 108 may further include one or more integrated passive devices IPD 109.

The semiconductor devices (104, 106a, 106b) may provide various functionality. For example, as described above, a first semiconductor device 104 may be configured as a SoC die stack. As also described above, the semiconductor package 300 may further include a first HBM die 107a and a second HBM die 107b. The first LSI 107a may provide fine-pitch electrical connections between the first semiconductor device 104 and the first HBM die 107a, and the second LSI 107b may provide fine-pitch electrical connections between the first semiconductor device 104 and the second HBM die 107b. The IPD 109 may be electrically connected to the SoC die stack 104 and may include one or more passive electrical components such as inductors, capacitors, resistors, diodes, etc. As such, the IPD 109 may provide additional electrical circuit functionality to the SoC die stack 104. For example, the IPD 109 may include one or more deep trench capacitors (DTC), in various embodiments.

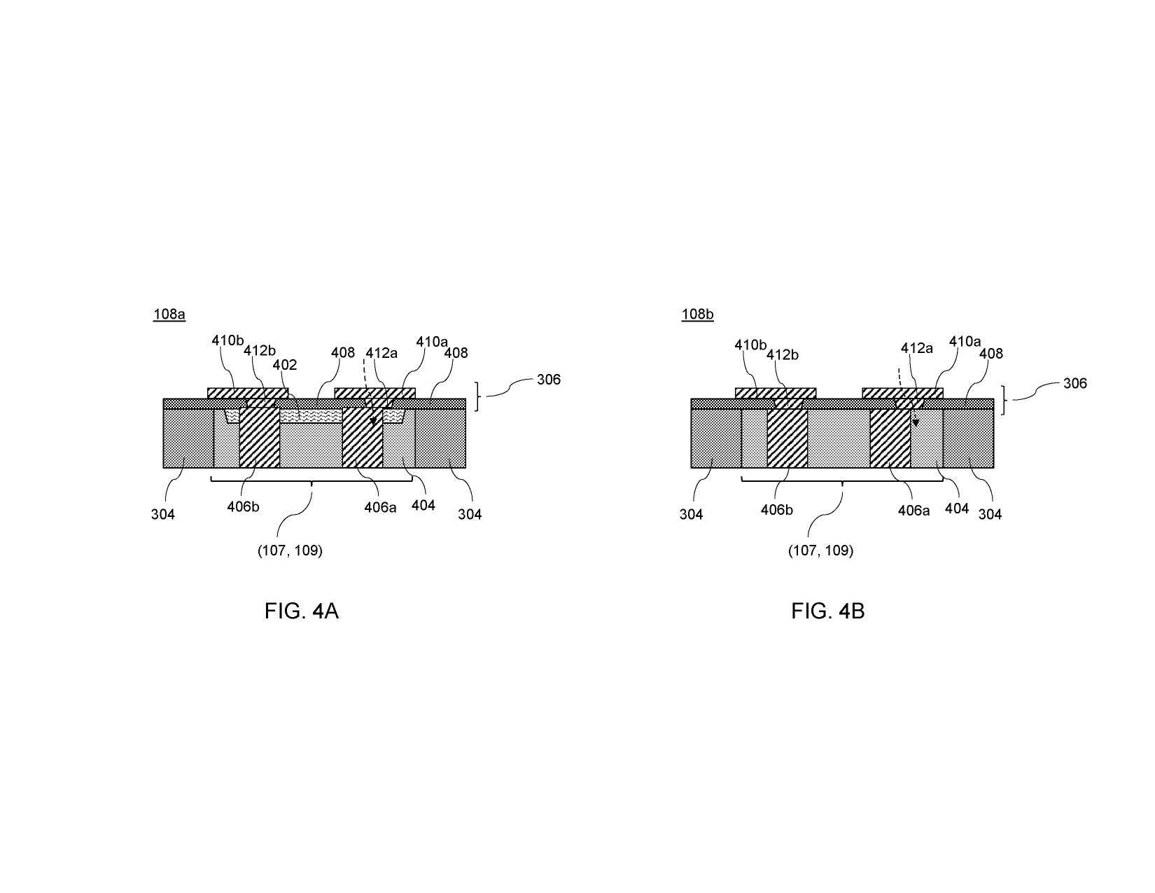

As shown in FIG. 3A and FIG. 3B, the interposer 108 may further include various redistribution layers (RDL) 306. As shown in FIG. 3A, the RDLs 306 may have an interconnect pitch that is relatively wide compared to the pitch of interconnects provided by the LSI (107a, 107b). The semiconductor devices (104, 106a, 106b) may be electrically connected to the RDLs 306 on a top side of the interposer 108, and the interposer108 may be electrically connected to the package substrate 110 through the RDLs 306 formed on the bottom side of the interposer 108. As shown in FIGS. 3A and 3B, the RDLs 306 may be formed over surfaces of the molding material 304 as well as over surfaces of the one or more active or passive semiconductor dies (107a, 107b, 109), as described in greater detail with reference to FIG. 4A, below.

FIG. 4A is a vertical cross-sectional view of a portion of an interposer 108a including an active or passive semiconductor die (107, 109) having a dielectric isolation layer 402, according to various embodiments. FIG. 4B is a vertical cross-sectional view of a portion of a comparison interposer 108b including a semiconductor die (107, 109) that omits the dielectric isolation layer 402. As shown, the semiconductor die (107, 109) may include a semiconductor substrate 404 and one or more electrical contacts (406a, 406b) formed in the semiconductor substrate 304. According to some embodiments, the semiconductor substrate 304 may be a silicon substrate and the one or more electrical contacts 406 may be through-silicon-vias (TSV). The interposer 108b may further include an RDL 306.

The RDL 306 may include a polymer layer 408 formed over the semiconductor die (107, 109) and the molding material 304 such that the polymer layer 408 is at least partially covering the dielectric isolation layer 402. The RDL 306 may further include at least one redistribution interconnect (410a, 410b) formed in the polymer layer 408. The RDL 306 may further include one or more redistribution vias (412a, 412b) that electrically connect the one or more electrical contacts 406 to respective redistribution interconnects 410a, 410 b (collectively 410).

The presence of the dielectric isolation layer 402 may be advantageous in that the dielectric isolation layer 402 may prevent electrically conducting pathway from forming between the one or more redistribution via (412a, 412b) and the semiconductor substrate 404. In this regard, due to process variations and differences in coefficients of thermal expansion (CTE), there may be instances in which one or both of the redistribution vias (412a, 412b) may be misaligned relative to respective electrical contacts (406a, 406b). For example, as shown in FIG. 4A, the first redistribution via 412a may be slightly misaligned relative to the first electrical contact 406a. As such, the first redistribution via 412a may be partially in contact with the first electrical contact 406a and partially in contact with the dielectric isolation layer 402. As such, the dielectric isolation layer 402 may prevent electrical current from flowing between the first redistribution via 412a and the semiconducting substrate 404, is indicated by the dashed arrow in FIG. 4A. In contrast, as shown in FIG. 4B, without the dielectric isolation layer 402, electrical current may flow from the first redistribution via 412a into the semiconductor substrate 404, as indicated by the dashed arrow in FIG. 4B.

FIGS. 5A, 5B, and 5C are vertical cross-sectional views of respective intermediate structures 500a, 500b, and 500c that may be used in the formation of an interposer 108 (108a, 108b), according to various embodiments. The intermediate structure 500a may include a carrier substrate 502 having a seed layer 504 formed thereon. The seed layer 504 may be formed by sputtering. The intermediate structure 500b of FIG. 5B may include a patterned photoresist 506 formed over the seed layer 504. The patterned photoresist may include openings 508 formed in the patterned photoresist 506. In the intermediate structure 500c of FIG. 5C, the TIVs 302 may be formed by electroplating a metallic fill material (such as copper, nickel, or a stack of copper and nickel) into the openings 508 of the patterned photoresist 506 of the intermediate structure 500b of FIG. 5B.

The metallic seed layer 504 may include, for example, a stack of a titanium barrier layer and a copper seed layer. The titanium barrier layer may have thickness in a range from 50 nm to 400 nm, and the copper seed layer may have a thickness in a range from 100 nm to 500 nm. The metallic fill material may include copper, nickel, or copper and nickel. Other suitable metallic fill materials are within the contemplated scope of disclosure. After forming the TIVs 302, the patterned photoresist 506 may then be removed by ashing or dissolution in a solvent. Portions of the seed layer 504 may then be etched in regions between the electroplated metallic fill material portions to generate the TIVs 302 as separated structures formed on the carrier substrate 502 as shown, for example, in FIG. 5D.

FIG. 5D is a vertical cross-sectional view of a further intermediate structure 500d that may be used in forming the interposer 108, according to various embodiments. As shown, the intermediate structure 500d may include the TIVs 302 attached to the carrier substrate 502, which may be formed by the process described with reference to FIGS. 5A to 5C, above. The intermediate structure 500d may further include a one or more semiconductor dies (107, 109). The one or more semiconductor dies (107, 109) may be attached to the carrier substrate 502 using an adhesive layer (not shown).

FIG. 5E is a vertical cross-sectional view of a further intermediate structure 500e that may be used in forming the interposer 108, according to various embodiments. The intermediate structure 500e may be formed from the intermediate structure 500d by forming a molding material 304 around the one or more semiconductor dies (107, 109) and the TIVs 302. The molding material 304 may be epoxy molding compound (EMC) that may be applied to the gaps between contiguous assemblies of one or more semiconductor dies (107, 109) and the TIVs 302. The molding material 304 may be configured to provide mechanical support for the one or more semiconductor dies (107, 109) and the TIVs 302. The EMC may include an epoxy-containing compound that may be hardened (i.e., cured) to provide a dielectric material portion having sufficient stiffness and mechanical strength. In this regard, Young’s modulus of pure epoxy is about 3.35 GPa, and Young’s modulus of the molding material 304 may be higher than Young’s modulus of pure epoxy by adding additives. Young’s modulus of the molding material 304 may be greater than 3.5 GPa.

The EMC may include epoxy resin, hardener, silica (as a filler material), and other additives. The EMC may be provided in a liquid form or in a solid form depending on the viscosity and flowability. Liquid EMC may provide better handling, good flowability, fewer voids, better fill, and less flow marks. Solid EMC provides less cure shrinkage, better stand-off, and less die drift. A high filler content (such as 85% in weight) within an EMC may shorten the time in mold, lower the mold shrinkage, and reduce the mold warpage. Uniform filler size distribution in the EMC may reduce flow marks and may enhance flowability. The curing temperature of the EMC may be in a range from 125 °C to 150 °C. Portions of the molding material 304 that overlies a horizontal plane (including top surfaces of the one or more semiconductor dies (107, 109)) may be removed by a planarization process (e.g., using chemical mechanical planarization (CMP)).

FIG. 5F is a vertical cross-sectional view of a further intermediate structure 500f that may be used in the formation of an interposer 108, according to various embodiments. The intermediate structure 500f may be formed from the intermediate structure of 500e of FIG. 5E by forming a patterned photoresist 506 over the intermediate structure 500f. In this regard, a blanket layer of photoresist (not shown) may be formed over the intermediate structure of 500e. The blanket layer of photoresist may then be patterned using lithographic techniques to thereby generate openings 508 in the patterned photoresist 506. The patterned photoresist 506 may then be used as an etch mask to etch the intermediate structure 500f. As shown, the patterned photoresist 506 may be used to mask portions of the molding material 304, the TIVs 302, and a portion of the silicon substrate 404 of the one or more semiconductor dies (107, 109). Etchant materials 510 may then be introduced to etch a portion of the silicon substrate 404. For example, a dry etch may be performed by introducing plasma etchant gases 510. In other embodiments, a wet etch process may be performed.

FIG. 5G is a vertical cross-sectional view of a further intermediate structure 500g that may be used in the formation of an interposer 108, according to various embodiments. The intermediate structure 500g may be formed from the intermediate structure of 500f of FIG. 5F by removing the patterned photoresist 506 from the intermediate structure 500f, after the above-described etch process has been performed. In this regard, the patterned photoresist 506 may be removed by ashing or by dissolution with a solvent. As shown in FIG. 5G, the etch process may act to remove a portion of the semiconductor substrate 404 to thereby generate a recessed region 512. In this regard, a first protruding portion 514a of the first electrical contact 406a and a second protruding portion 514b of the second electrical contact 406b may be exposed and may each thereby protrude from a surface 516 of the semiconductor substrate 404.

FIG. 5H is a vertical cross-sectional view of a further intermediate structure 500h that may be used in the formation of an interposer 108, according to various embodiments. The intermediate structure 500h may be formed from the intermediate structure of 500g of FIG. 5G by depositing a dielectric material 402L over the intermediate structure 500g of FIG. 5E. In this regard, the dielectric material 402L may be deposited over the surface 516 of the semiconductor substrate 404 and over the first electrical contact 406a and the second electrical contact 406b. As shown, the dielectric material 402L may also be deposited over portions of the molding material 304. According to an embodiment, the dielectric material 402L may be a polymer material. For example, the polymer may be polyimide (PI), benzocyclobutene (BCB), or polybenzo-bisoxazole (PBO). Various other polymer materials may be used in other embodiments. The polymer material 402L may be deposited using a spin-on technique, or may be deposited using various other deposition techniques such as by vapor-deposition polymerization, by chemical vapor deposition (CVD), etc.

FIG. 5I is a vertical cross-sectional view of a further intermediate structure 500i that may be used in the formation of an interposer 108, according to various embodiments. The intermediate structure 500i may be formed from the intermediate structure of 500h of FIG. 5H by performing a planarization process (e.g., using chemical mechanical planarization (CMP)) to remove a portion of the dielectric material 402L from a top surface of the intermediate structure 500i. As shown, the planarization process may be performed to remove a sufficient amount of the dielectric material 402L to thereby expose a first contact surface 520a of the first electrical contact 406a and a second contact surface 520b of the second electrical contact 406b.

In this regard, the dielectric isolation layer 402, described above with reference to FIG. 4A, may be formed of the remaining portion of the dielectric material 402L after the planarization process is performed. As shown in FIG. 5I, the dielectric isolation layer 402 may be located between the surface 516 of the semiconductor substrate 304 and a plane parallel to the first contact surface 520a, of the first electrical contact 406a, and the second contact surface 520b of the second electrical contact 406b. Further, as shown in FIG. 5I, the dielectric isolation layer 402 may laterally surround the first protruding portion 514a of the first electrical contact 406a and the second protruding portion 514b of the second electrical contact 406b while leaving the respective first contact surface 520a and the second contact surface 520b exposed.

FIG. 5J is a vertical cross-sectional view of a further intermediate structure 500j that may be used in the formation of an interposer 108, according to various embodiments. The intermediate structure 500j may be formed from the intermediate structure of 500i of FIG. 5I by forming a redistribution layer 306 over a top surface of the intermediate structure 500i of FIG. 5I. In this regard, the redistribution layer 306 may be formed by depositing a polymer layer 408 over the one or more semiconductor dies (107, 109) and the molding material 304 such that the polymer layer 408 is at least partially covering the dielectric isolation layer 402. Redistribution vias (412a, 412b, 412c) and redistribution interconnects (410a, 410b, 410c) may then be formed in the polymer layer 408 such that electrical connections may be formed between the redistribution interconnects (410a, 410b, 410c) and respective contact surfaces (520a, 520b, 520c) of the electrical contacts (406a, 406b) and the TIVs 302, respectively.

In this regard, the polymer layer 408 may be patterned using lithographic processes to generate via holes (not shown). A seed layer (e.g., including Ti/Cu or other conductive material) may then be deposited over exposed contact surfaces (520a, 520b, 520c) and over remaining surfaces of the polymer layer 408. A patterned photoresist (not shown) may then be formed over the polymer layer 408 such that regions that are not masked by the patterned photoresist include the via holes and regions of the polymer layer 408 over which the redistribution interconnects (410a, 410b, 410c) may be subsequently formed. The redistribution vias (412a, 412b, 412c and redistribution interconnects (410a, 410b, 410c) may then be formed by deposition of a conducting material. For example, according to an embodiment, copper may be deposited by performing an electroplating process to thereby form the redistribution vias (410a, 410b, 410c) and redistribution interconnects (410a, 410b, 410c). Various other conducting material may be used in other embodiments.

As further shown in FIGS. 5I and 5J, the dielectric isolation layer 402 may be configured to laterally extend beyond the first contact surface 520a and the second contact surface 520a. As such, any misalignment between the redistribution vias (412a, 412b) and the contact surfaces (520a, 520b) may only cause one or both of the redistribution vias (412a, 412b) to partially contact the contact surface (520a, 520b) and the dielectric isolation layer 402. As such, the redistribution vias (412a, 412b) may be prevented from contacting the semiconductor substrate 404 as shown, for example, in FIG. 4A and described in greater detail above. In this way, the dielectric isolation layer 402 may prevent an electrically conducting pathway from forming between the one or both of the redistribution vias (412a, 412b) and the semiconductor substrate 404. Therefore, the undesirable electrically conducting pathway, shown as the dashed arrow in FIG. 4B, may be avoided.

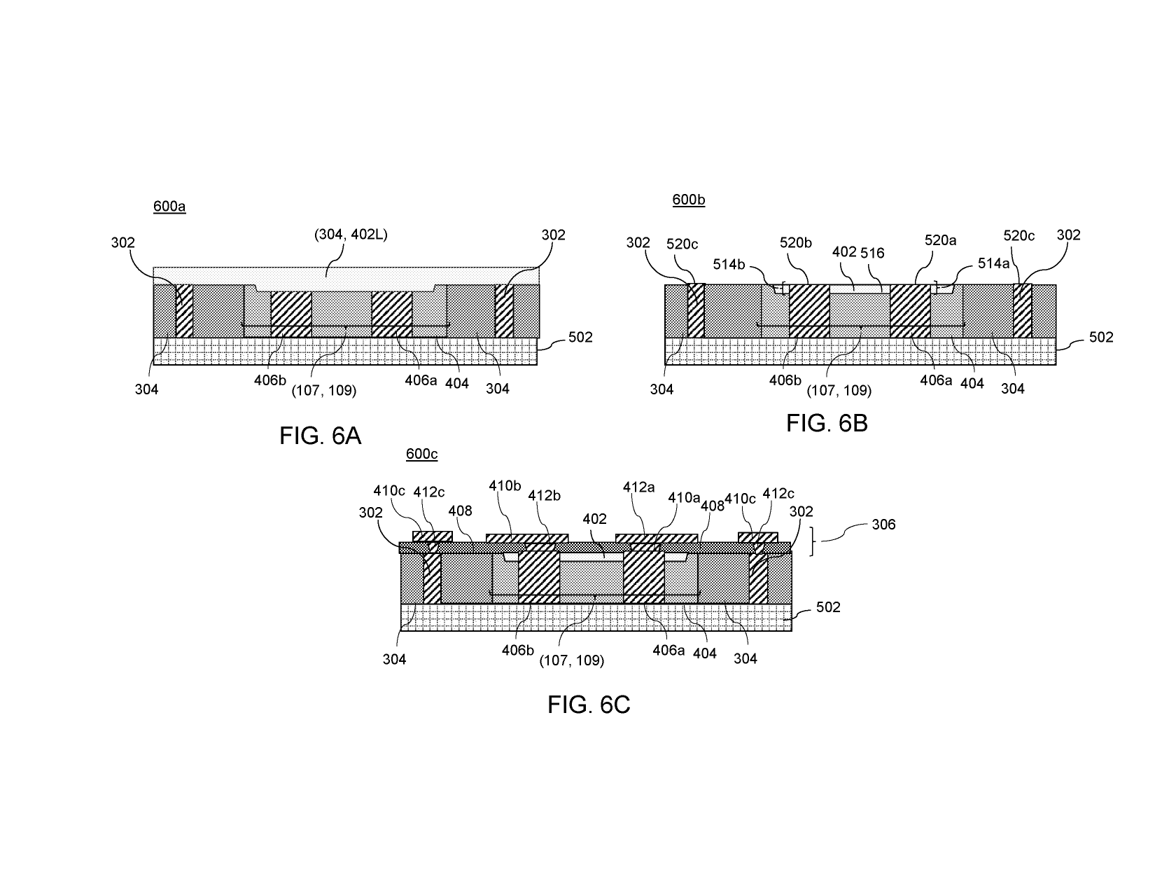

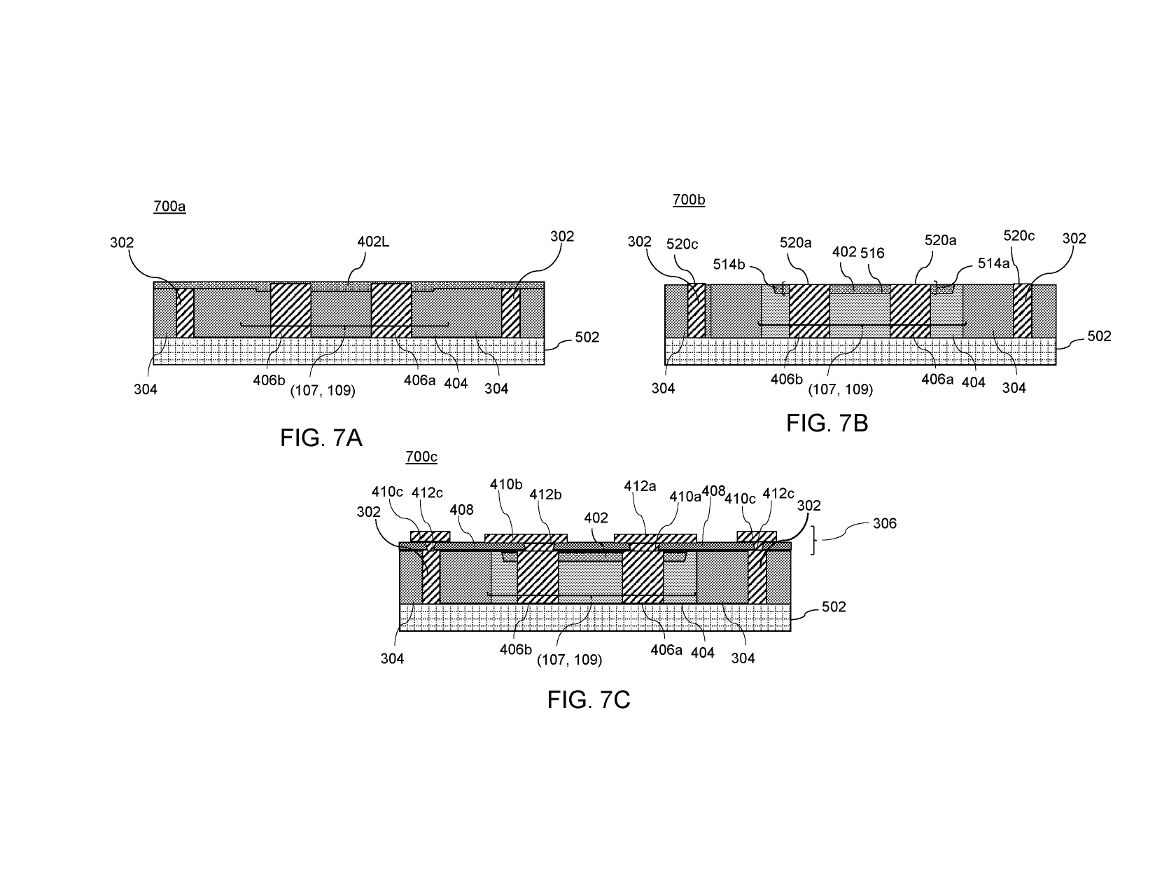

FIGS. 6A to 7C are vertical cross-sectional views of respective further intermediate structures (600a to 700c) that may be used in the formation of an interposer 108, according to various embodiments. In this regard, FIGS. 6A and 7A correspond to alternative intermediate structures corresponding to the intermediate structure 500h of FIG. 5H; FIGS. 6B and 7B correspond to alternative intermediate structures corresponding to the intermediate structure 500i of FIG. 5I; and FIGS. 6C and 7C correspond to alternative intermediate structures corresponding to the intermediate structure 500i of FIG. 5J. In this regard, processing operations similar to those described above with reference to the intermediate structures (500h, 500i, 500j) of FIGS. 5H, 5I, and 5J, may be performed with reference to the intermediate structures (600a, 600b, 600c) FIGS. 6A, 6B, and 6C, in one embodiment, and with reference to the intermediate structures (700a, 700b, 700c) of FIGS. 7A, 7B, and 7C, in another embodiment.

In embodiments related to the intermediate structures (600a, 600b, 600c) FIGS. 6A, 6B, and 6C, a molding material (304, 402L) may be used as the dielectric material 402L. The molding material (304, 402L) may be similar to the molding material 304 used to surround the one or more semiconductor dies (107, 109) described above. For example, the molding material may be an epoxy based molding material that may or may not include various reinforcement materials. In some embodiments, the molding material (304, 402L) may be the same material as used to form the interposer 108. In other embodiments, different materials may be used for the molding material 304 of the interposer 108 and for the dielectric material 402L used to form the dielectric isolation layer 402.

In embodiments related to the intermediate structures (700a, 700b, 700c) of FIGS. 7A, 7B, and 7C, the dielectric material 402L may be a thin insulating material layer that may be deposited using a conformal deposition process. For example, the dielectric material 402L may include SiN, SiC, etc., that may be deposited using a CVD deposition process. As with other embodiments, a planarization process may be performed to remove an excess portion of the dielectric material 402L and to thereby expose the contact surfaces (520a, 520b, 520c) of the electrical contacts (406a, 406b) and the TIVs 320. Additional polishing and/or chemical treatment operations may be performed as needed to remove any residual materials (e.g., CuOₓ residue).

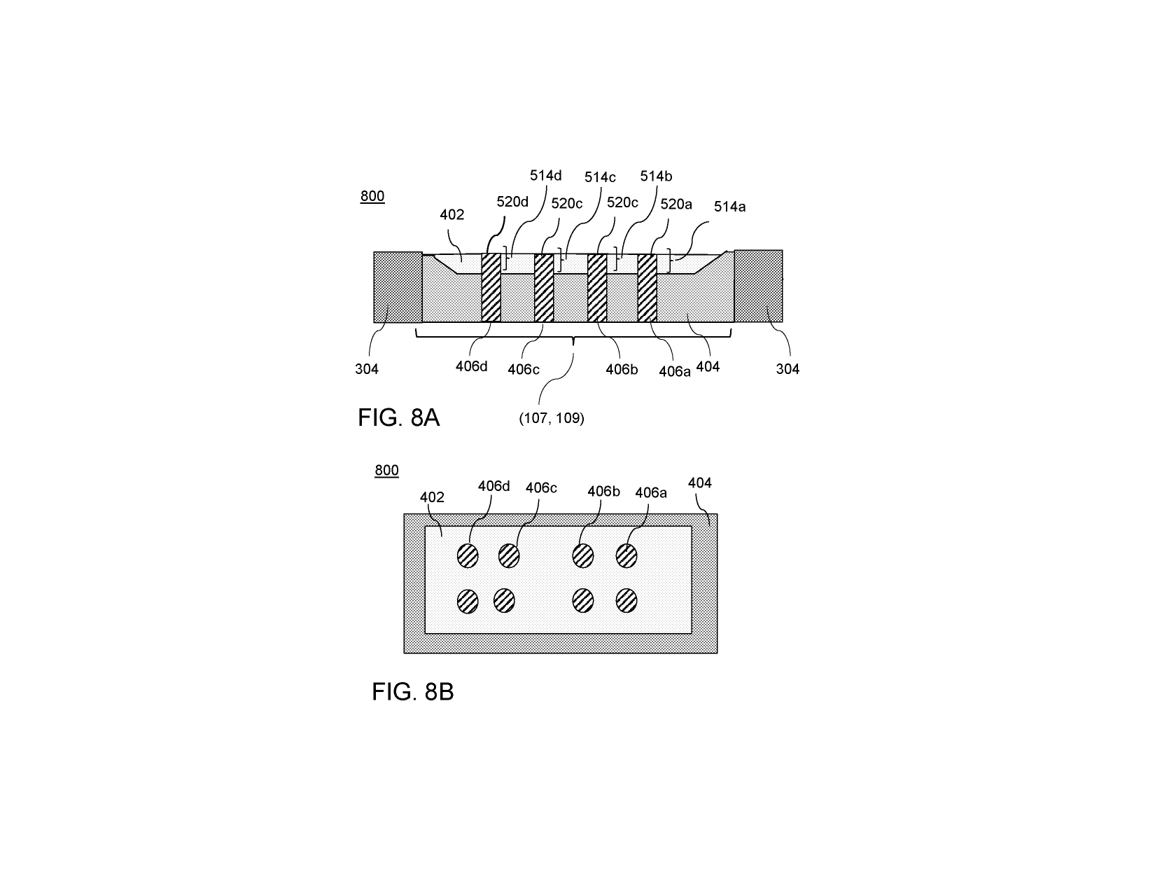

FIG. 8A is a vertical cross-sectional view of a portion 800 of an interposer 108 including a semiconductor die (107, 109) having a dielectric isolation layer 402 in a first configuration, and FIG. 8B is top view of the portion of the interposer of FIG. 8A, according to various embodiments. As shown in FIGS. 8A and 8B, the dielectric isolation layer 402 may include a single portion that laterally surrounds both the protruding portions (514a, 514b, 514c, 514d) of each of a respective plurality of electrical contacts (406a, 406b, 406c, 406d). As described above, each of the plurality of electrical contacts (406a, 406b, 406c, 406d) may be formed as a TSV or other type of electrical contact.

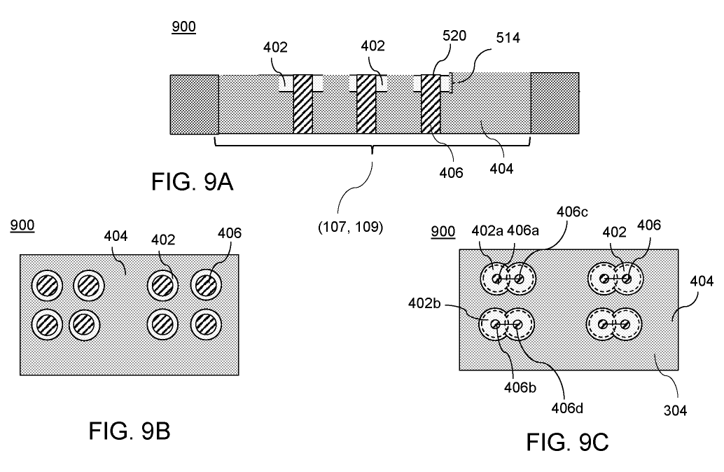

FIG. 9A is a vertical cross-sectional view of a portion 900 of an interposer 800 including a semiconductor die (107, 109) having a dielectric isolation layer 402 in a further configuration, according to various embodiments. FIG. 9B is top view of the portion of the interposer of FIG. 9A, and FIG. 9C is top view of a portion of an interposer in an alternative configuration to that of FIG. 9B, according to various embodiments. As shown in FIGS. 9B and 9C, the dielectric isolation layer 402 may include a plurality of disconnected portions. For example, as shown in FIG. 9B, the dielectric isolation layer 402 may include portions that surround respective electrical contacts 406.

Alternatively, one or more portions of the dielectric isolation layer 402 may have separated portions that surround two or more electrical contacts. For example, as shown in FIG. 9C, the dielectric isolation layer 402 may include a first portion 402a that laterally surrounds a first electrical contact 406a and a second portion 402b that laterally surrounds a second electrical contact 406b, such that the first portion 402a and the second portion 402b are disconnected from one another. In further embodiments, the semiconductor die (107, 109) may further include a third electrical contact 406c and a fourth electrical contact 406d, as shown in FIG. 9C. The first portion 402a of the dielectric isolation layer 402 may laterally surround a first protruding portion 514a of the first electric contact 406a and a third protruding portion 514c of the third electrical contact 406c. Similarly, the second portion 402b of the dielectric isolation layer 402 may laterally surround a second protruding portion 514b of the second electrical contact 406b and a fourth protruding portion 514d of the fourth electrical contact 406d. The dielectric isolation layer may be configured in various other ways in other embodiments.

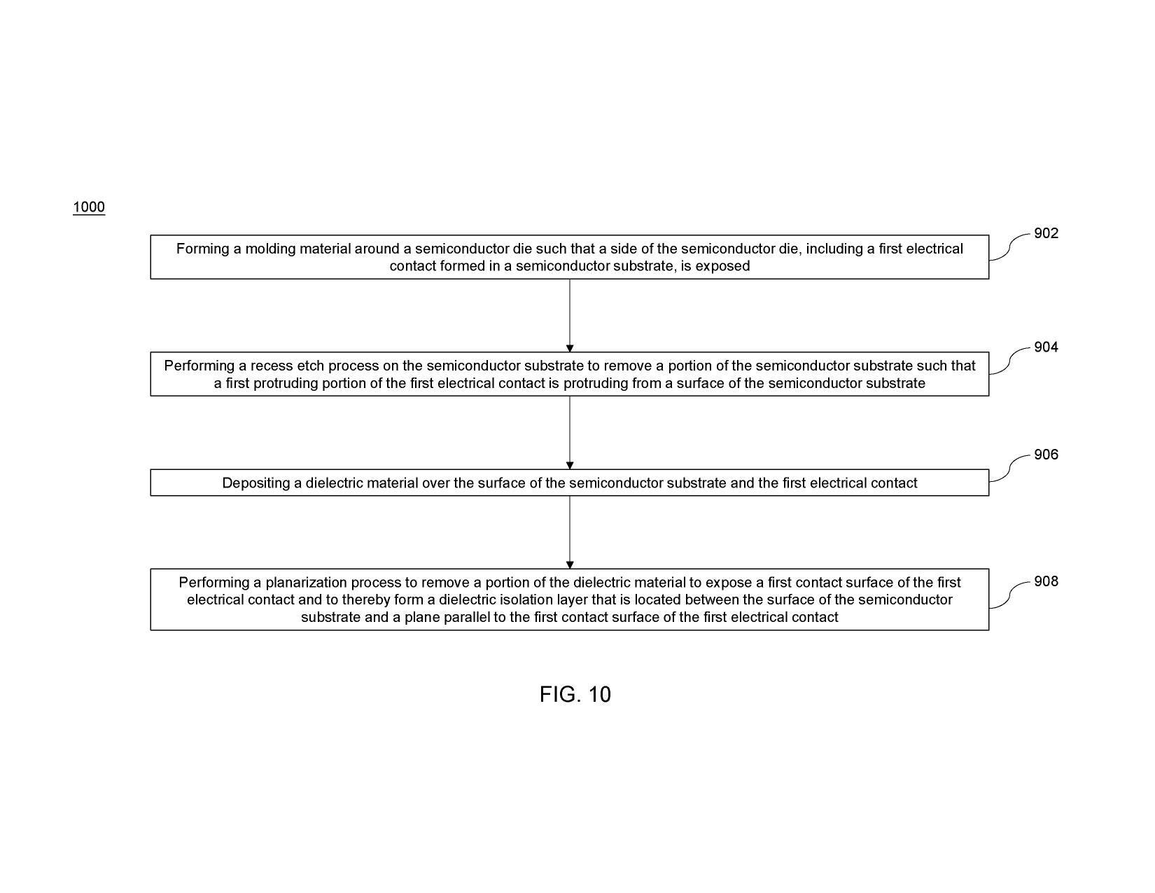

FIG. 10 is a flowchart illustration operations of a method 1000 of forming an interposer 108, according to various embodiments. In operation 902, the method 1000 may include forming a molding material 304 around a semiconductor die (107, 109) such that the molding material 304 laterally surrounds the semiconductor die (107, 109). The molding material 304 may be formed such that a side of the semiconductor die (107, 109), that includes a first electrical contact 406a formed in a semiconductor substrate 404, is exposed. In operation 904, the method 1000 may include performing a recess etch process on the semiconductor substrate 404 to remove a portion of the semiconductor substrate 404 such that a first protruding portion 514a of the first electrical contact 406a is protruding from a surface 516 of the semiconductor substrate 404. In operation 906, the method 1000 may include depositing a dielectric material 402L over the surface 516 of the semiconductor substrate 404 and the first electrical contact 406a.

In operation 908, the method 1000 may include performing a planarization process to remove a portion of the dielectric material 402L to expose a first contact surface 520a of the first electrical contact 406a and to thereby form a dielectric isolation layer 402 that is located between the surface 516 of the semiconductor substrate 404 and a plane parallel to the first contact surface 520a of the first electrical contact 406a. In this regard, the dielectric isolation layer 402 may laterally surround the first protruding portion 514a of the first electrical contact 406a without covering the first contact surface 520a of the first electrical contact 406a.

The method 1000 may further include forming a redistribution layer 306 by performing operations including: forming a polymer layer 408 over the semiconductor die (107, 109) and the molding material 304 such that the polymer layer 408 is at least partially covering the dielectric isolation layer 402; forming at least one redistribution interconnect (410a, 410b) in the polymer layer 408; and forming a first redistribution via 412a in the polymer layer 408 such that the first redistribution via 412a forms an electrical connection between the first contact surface 520a of the first electrical contact 406a and the at least one redistribution interconnect (410a, 410b).

The method 1000 may further include forming the dielectric isolation layer 402 to laterally extend beyond the first contact surface 520a such that any misalignment between the first redistribution via 412a and the first contact surface 520a only causes the first redistribution via 412a to partially contact the first contact surface 520a of the first electrical contact 406a and to partially contact the dielectric isolation layer 402, but not to contact the semiconductor substrate 404. In this regard, the dielectric isolation layer 402 may prevent an electrically conducting pathway from forming between the first redistribution via 412a and the semiconductor substrate 404.

According to various embodiments, the semiconductor die (107, 109) further may include a second electrical contact 406b including a second protruding portion 514b that protrudes from the surface 516 of the semiconductor substrate 404. The method 1000 may further include forming the dielectric isolation layer 402 to be located between the surface 516 of the semiconductor substrate 404 and a plane parallel to a second contact surface 520b of the second electrical contact 406b such that the dielectric isolation layer 402 laterally surrounds the second protruding portion 514b of the second electrical contact 406b without covering the second contact surface 520b of the second electrical contact 406b.

Referring to all drawings and according to various embodiments of the present disclosure, a semiconductor die (107, 109) is provided. The semiconductor die (107, 109) may include a silicon substrate 404, a first through-silicon-via (TSV) 406a formed in the silicon substrate 404, wherein the first TSV 406a may include a first protruding portion 514a that protrudes from a surface 516 of the silicon substrate 404, and a dielectric isolation layer 402 located between the surface 516 of the silicon substrate 404 and a plane parallel to a first contact surface 520a of the first TSV 406a. In this regard, the dielectric isolation layer 402 may laterally surround the first protruding portion 514a of the first TSV 406a without covering the first contact surface 520a of the first TSV 406a. In various embodiments, the dielectric isolation layer 402 may include an epoxy molding compound. Alternatively, the dielectric isolation layer 402 may include silicon nitride.

According to further embodiments, a redistribution layer 306 may be formed over the semiconductor die (107, 109). The redistribution layer 306 may include a polymer layer 408 formed over the semiconductor die (107, 109) such that the polymer layer 408 is at least partially covering the dielectric isolation layer 402. The redistribution layer 306 may include at least one redistribution interconnect (410a, 410b) formed in the polymer layer 408 and a first redistribution via 412a that forms an electrical connection between the first contact surface 520a of the first TSV 406a and the at least one redistribution interconnect (410a, 410b). Due to process variations, in some embodiments, the first redistribution via 412a may partially contact the first contact surface 520a of the first TSV 406a and may partially contact the dielectric isolation layer 402. In such configurations, the dielectric isolation layer 402 may prevent an electrically conducting pathway from forming between the first redistribution via 412a and the silicon substrate 404.

According to various embodiments, the semiconductor die (107, 109) may further include a second TSV 406b having a second protruding portion 514b that protrudes from the surface 516 of the silicon substrate 404. In such embodiments, the dielectric isolation layer 402 may be further formed between the surface 516 of the silicon substrate 404 and a plane parallel to a second contact surface 520b of the second TSV 406b such that the dielectric isolation layer 402 laterally surrounds the second protruding portion 514b of the second TSV 406b without covering the second contact surface 520b of the second TSV 406b. In various embodiments, the dielectric isolation layer 402 may include a single portion that laterally surrounds both the first protruding portion 514a of the first TSV 406a and the second protruding portion 514b of the second TSV 406b. In other embodiments, the dielectric isolation layer 402 may include a first portion 402a that laterally surrounds the first protruding portion 514a of the first TSV 406a and a second portion 402b that laterally surrounds the second protruding portion 514b of the second TSV 406b, such that the first portion 402a and the second portion 402b are disconnected from one another.

In still further embodiments, the semiconductor die (107, 109) may further include a third TSV 406c including a third protruding portion 514c that protrudes from the surface 516 of the silicon substrate 404 and a fourth TSV 406d including a fourth protruding portion 514d that protrudes from the surface 516 of the silicon substrate 404. The first portion 402a of the dielectric isolation layer 402 may laterally surround the first protruding portion 514a of the first TSV 406a and the third protruding portion 514c of the third TSV 406c. Similarly, the second portion 402b of the dielectric isolation layer 402 may laterally surround the second protruding portion 514b of the second TSV 406b and the fourth protruding portion 514d of the fourth TSV 406d.

Further, referring to all drawings and according to various embodiments of the present disclosure, an interposer 108 is provided. The interposer 108 may include a semiconductor die (107, 109) and a molding material 304 laterally surrounding the semiconductor die (107, 109). The semiconductor die (107, 109) may include a semiconductor substrate 404, a first electrical contact 406a including a first protruding portion 514a that protrudes from a surface 516 of the semiconductor substrate 404, and a dielectric isolation layer 402 located between the surface 516 of the semiconductor substrate 404 and a plane parallel to a first contact surface 520a of the first electrical contact 406a. The dielectric isolation layer 402 may laterally surround the first protruding portion 514a of the first electrical contact 406a without covering the first contact surface 520a of the first electrical contact 406a.

The interposer 108 may further include a redistribution layer 306, including a polymer layer 408 formed over the semiconductor die (107, 109) and the molding material 304 such that the polymer layer 408 is at least partially covering the dielectric isolation layer 402. The redistribution layer 306 may further include at least one redistribution interconnect (410a, 410b) formed in the polymer layer 408, and a first redistribution via 412a that electrically connects the first contact surface 520a of the first electrical contact 406a and the at least one redistribution interconnect (410a, 410b). Due to process variations, in some embodiments, the first redistribution via 412a may partially contact the first contact surface 520a of the first electrical contact 406a and may partially contact the dielectric isolation layer 402. In such embodiments, the dielectric isolation layer 402 may prevent an electrically conducting pathway from forming between the first redistribution via 412a and the semiconductor substrate 404. In some embodiments, the semiconductor substrate 404 may include silicon and the first electrical contact 406a may be formed as a TSV. In some embodiments, the dielectric isolation layer 402 may include silicon nitride. In still-further embodiments, each of the dielectric isolation layer 402 and the molding material 304 include an epoxy molding material 304.

In certain embodiments, interposer 108 may further include a second electrical contact 406b including a second protruding portion 514b that protrudes from the surface 516 of the semiconductor substrate 404. In such embodiments, the dielectric isolation layer 402 may be further formed between the surface 516 of the semiconductor substrate 404 and a plane parallel to a second contact surface 520b of the second electrical contact 406b such that the dielectric isolation layer 402 laterally surrounds the second protruding portion 514b of the second electrical contact 406b but does not cover the second contact surface 520b of the second electrical contact 406b.

The above-described embodiments may provide advantages over existing semiconductor package structures. In this regard, disclosed embodiments may provide an interposer 108 that includes a semiconductor die (107, 109) having a dielectric isolation layer 402 formed between a surface 516 of a semiconductor substrate 404 and a plane parallel to a contact surface (520a, 520b) of an electrical contact (406a, 406b) of the semiconductor die (107, 109). In forming redistribution layers 306 over the semiconductor die (107, 109), some redistribution vias (412a, 412b) that are intended to be electrically connected to electrical contacts (406a, 406b) of the semiconductor die (107, 109) may be misaligned due to process variations. Such misalignment may lead to some redistribution vias (412a, 412b) making partial contact with the respective electrical contacts (406a, 406b) and making partial contact with the dielectric isolation layer 402. The presence of the dielectric isolation layer 402 may thereby prevent unwanted electrical leakage between redistribution interconnects (410a, 410b)/vias (412a, 412b) and the semiconductor substrate 404, which may otherwise occur in comparative embodiments that do not include the dielectric isolation layer 402.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor die, comprising:
a silicon substrate;
a first through-silicon-via (TSV) formed in the silicon substrate, wherein the first TSV comprises a first protruding portion that protrudes from a surface of the silicon substrate; and
a dielectric isolation layer located between the surface of the silicon substrate and a plane parallel to a first contact surface of the first TSV such that the dielectric isolation layer laterally surrounds the first protruding portion of the first TSV but does not cover the first contact surface of the first TSV.

2. The semiconductor die of claim 1, wherein the dielectric isolation layer comprises an epoxy molding compound.

3. The semiconductor die of claim 1, wherein the dielectric isolation layer comprises silicon nitride.

4. The semiconductor die of claim 1, further comprising a redistribution layer formed over the semiconductor die, comprising:
a polymer layer formed over the semiconductor die such that the polymer layer is at least partially covering the dielectric isolation layer;
at least one redistribution interconnect formed in the polymer layer; and
a first redistribution via that forms an electrical connection between the first contact surface of the first TSV and the at least one redistribution interconnect.

5. The semiconductor die of claim 4, wherein the first redistribution via partially contacts the first contact surface of the first TSV and partially contacts the dielectric isolation layer, and
wherein the dielectric isolation layer prevents an electrically conducting pathway from forming between the first redistribution via and the silicon substrate.

6. The semiconductor die of claim 1, further comprising:
a second TSV comprising a second protruding portion that protrudes from the surface of the silicon substrate,
wherein the dielectric isolation layer is further formed between the surface of the silicon substrate and a plane parallel to a second contact surface of the second TSV such that the dielectric isolation layer laterally surrounds the second protruding portion of the second TSV but does not cover the second contact surface of the second TSV.

7. The semiconductor die of claim 6, wherein the dielectric isolation layer comprises a single portion that laterally surrounds both the first protruding portion of the first TSV and the second protruding portion of the second TSV.

8. The semiconductor die of claim 6, wherein the dielectric isolation layer comprises a first portion that laterally surrounds the first protruding portion of the first TSV and a second portion that laterally surrounds the second protruding portion of the second TSV, such that the first portion and the second portion are disconnected from one another.

9. The semiconductor die of claim 8, further comprising:
a third TSV comprising a third protruding portion that protrudes from the surface of the silicon substrate; and
a fourth TSV comprising a fourth protruding portion that protrudes from the surface of the silicon substrate,
wherein the first portion of the dielectric isolation layer laterally surrounds the first protruding portion of the first TSV and the third protruding portion of the third TSV, and
wherein the second portion of the dielectric isolation layer laterally surrounds the second protruding portion of the second TSV and the fourth protruding portion of the fourth TSV.

10. An interposer, comprising:
a semiconductor die;
a molding material laterally surrounding the semiconductor die,
wherein the semiconductor die comprises:
a semiconductor substrate;
a first electrical contact comprising a first protruding portion that protrudes from a surface of the semiconductor substrate; and
a dielectric isolation layer located between the surface of the semiconductor substrate and a plane parallel to a first contact surface of the first electrical contact such that the dielectric isolation layer laterally surrounds the first protruding portion of the first electrical contact but does not cover the first contact surface of the first electrical contact.

11. The interposer of claim 10, further comprising a redistribution layer, comprising:
a polymer layer formed over the semiconductor die and the molding material such that the polymer layer is at least partially covering the dielectric isolation layer;
at least one redistribution interconnect formed in the polymer layer; and
a first redistribution via that electrically connects the first contact surface of the first electrical contact and the at least one redistribution interconnect.

12. The interposer of claim 11, wherein the first redistribution via partially contacts the first contact surface of the first electrical contact and partially contacts the dielectric isolation layer, and
wherein the dielectric isolation layer prevents an electrically conducting pathway from forming between the first redistribution via and the semiconductor substrate.

13. The interposer of claim 11, wherein the semiconductor substrate comprises silicon and the first electrical contact is a TSV.

14. The interposer of claim 11, wherein the dielectric isolation layer comprises silicon nitride.

15. The interposer of claim 11, wherein each of the dielectric isolation layer and the molding material comprise an epoxy molding material.

16. The interposer of claim 11, further comprising:
a second electrical contact comprising a second protruding portion that protrudes from the surface of the semiconductor substrate,
wherein the dielectric isolation layer is further formed between the surface of the semiconductor substrate and a plane parallel to a second contact surface of the second electrical contact such that the dielectric isolation layer laterally surrounds the second protruding portion of the second electrical contact but does not cover the second contact surface of the second electrical contact.

17. A semiconductor package, comprising:
a package substrate;
an interposer mounted on the package substrate, the interposer comprising:
a semiconductor die embedded in a molding material, wherein the semiconductor die comprises:
a semiconductor substrate;
an electrical contact formed in the semiconductor substrate, the electrical contact comprising a protruding portion that protrudes from a surface of the semiconductor substrate; and
a dielectric isolation layer located between the surface of the semiconductor substrate and a plane parallel to a contact surface of the electrical contact such that the dielectric isolation layer laterally surrounds the protruding portion of the electrical contact without covering the contact surface of the electrical contact; and
a redistribution layer formed over the semiconductor die and the molding material, the redistribution layer comprising a redistribution via electrically connected to the contact surface of the electrical contact; and
a semiconductor device mounted on the interposer and electrically connected to the redistribution layer.

18. The semiconductor package of claim 17, wherein the redistribution via partially contacts the contact surface of the electrical contact and partially contacts the dielectric isolation layer.

19. The semiconductor package of claim 17, wherein the semiconductor device comprises a system-on-chip die stack or a high bandwidth memory die stack.

20. The semiconductor package of claim 17, wherein the interposer comprises a through-interposer-via formed in the molding material, the through-interposer-via electrically connecting the redistribution layer to the package substrate.
